(19) United States
(12) Patent Application Publication
(10) Pub. No.: US 2009/0002947 A1
(43) Pub. Date: Jan. 1, 2009

(54) Evaporative cooling system for electronic components

(75) Inventors: Nyles I. Nettleton, Campbell, CA (US); Howard L. Davidson, San Carlos, CA (US)

Correspondence Address: Henry C. Query, Jr., 504 S. Pierce Avenue, Wheaton, IL, 60187, US

(73) Assignee: Xcelaero Corporation, San Luis Obispo, CA (US)

(21) Appl. No.: 12/082,640

(22) Filed: Apr. 11, 2008

Related U.S. Application Data
(60) Provisional application No. 60/923,480, filed on Apr. 13, 2007.

(51) Int. Cl. H05K 7/20

(52) U.S. Cl. 361/700

(57) ABSTRACT

An apparatus for cooling a number of electronic components comprises an enclosure within which the components are positioned, an arrangement for circulating a cooling fluid to the components so that the cooling fluid can evaporate on or proximate the components and thereby absorb the heat generated by the components, a mechanism for condensing the evaporated cooling fluid, and a reservoir which is in fluid communication with the circulating means and within which the condensed cooling fluid collects.

This application is based on and claims the benefit of U.S. Provisional Patent Application No. 60/923,480, which was filed on Apr. 13, 2007.

### BACKGROUND OF THE INVENTION

The present invention relates to an apparatus and method for cooling electrical components. In particular, the invention relates to an apparatus and method in which the components are surrounded by an enclosure, a cooling fluid is evaporated onto the components to cool them, and then the heat from the vaporous cooling fluid is dissipated through the enclosure and into the surrounding environment.

### SUMMARY OF THE INVENTION

In accordance with the present invention, an apparatus for cooling a number of electronic components comprises an enclosure within which the components are positioned, means for circulating a cooling fluid to the components, wherein the cooling fluid evaporates on or proximate the components and thereby absorbs the heat generated by the components, means for condensing the evaporated cooling fluid, and a reservoir which is in fluid communication with the circulating means and within which the condensed cooling fluid collects.

In accordance with one aspect of the invention the enclosure defines a hermetically sealed volume within which the components are positioned. In accordance with a further aspect of the invention the components are mounted on a circuit board and the enclosure is secured and sealed to the circuit board over the components.

The condensing means may comprise a surface of the enclosure. Alternatively, the condensing means may comprise a number of condenser tubes which are connected to or formed integrally with the enclosure. In one embodiment of the invention the condensing means comprises a plurality of condensing tubes which each extend generally vertically from an upper surface of the enclosure.

In accordance with one embodiment of the invention the circulating means comprises a pump which is fluidly connected to the reservoir, a number of applicators which are positioned proximate the components, and a fluid distribution network which is connected between the pump and the applicators. In this manner, the cooling fluid is circulated by the pump through the fluid distribution network and the applicators to the components. The fluid distribution network may comprise, e.g., a manifold which is formed within one or more surfaces of the enclosure.

In accordance with another embodiment of the invention the reservoir may comprise a portion of the sealed volume within which the components are positioned. In accordance with another embodiment of the invention the reservoir may comprise a catch tray which is secured to the circuit board opposite the components. In yet another embodiment of the invention the reservoir may communicate with the sealed volume through a number of apertures in the circuit board.

The present invention is also directed to a method for cooling a number of electronic components. The method comprises the steps of: (a) positioning the components within a sealed enclosure; (b) circulating a cooling fluid to the components; (c) evaporating the cooling fluid on or adjacent the components to thereby absorb the heat generated by the components; (d) condensing the evaporated cooling fluid within the enclosure; (e) collecting the condensed cooling fluid; and (f) repeating steps (a) through (e).

The objects and advantages of the present invention will be made apparent from the following detailed description, with reference to the accompanying drawings. In the drawings, the same reference numbers are used to denote similar components in the various embodiments.

### BRIEF DESCRIPTION OF THE DRAWINGS

FIG. 1 is a perspective view of one embodiment of the evaporative cooling apparatus of the present invention shown positioned over an exemplary circuit board;

FIG. 2 is a perspective view of the evaporative cooling apparatus of FIG. 1 shown assembled on the circuit board;

FIG. 3 is a top perspective view of another embodiment of the evaporative cooling apparatus of the present invention; and

FIG. 4 is a bottom perspective view of the evaporative cooling apparatus shown in FIG. 3.

### DETAILED DESCRIPTION OF THE INVENTION

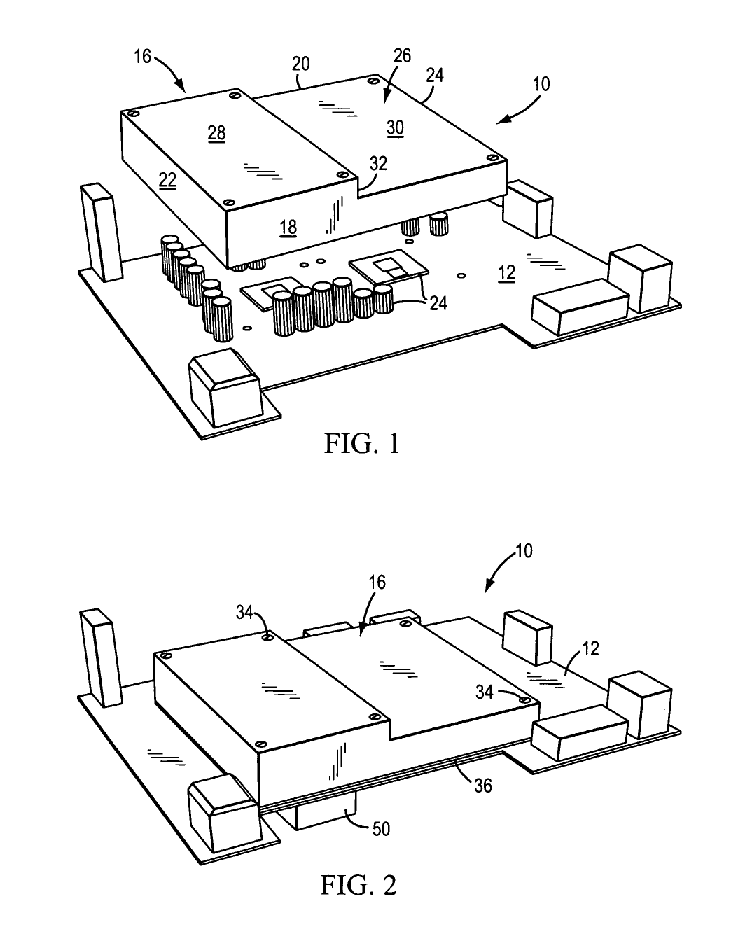

Referring to FIGS. 1 and 2, the evaporative cooling apparatus of the present invention, which is indicated generally by reference number 10, is shown in conjunction with an exemplary circuit board 12 which comprises a number of electronic components 14 mounted thereon. The circuit board 12 may be mounted in a device (not shown), such as a computer or a game consol. In use of the device, the electronic components 14 may generate a significant amount of heat which could adversely affect the performance of the components and, thus, the device. In accordance with the present invention, the evaporative cooling apparatus 10 provides an efficient and effective means for dissipating this heat from the components 14.

The evaporative cooling apparatus 10 comprises an enclosure 16 which is secured to the circuit board 12 over the electronic components 14. The enclosure 16 may be configured to cover all or desired ones of the components 14. Accordingly, the enclosure 16 may have any of a variety of forms. In the embodiment of the invention illustrated in FIGS. 1 and 2, for example, the enclosure 16 comprises a front wall 18, a rear wall 20, and a pair of side walls 22, 24. The enclosure 16 also comprises a top surface 26 which extends completely between these walls. The top surface 26 may comprise a number of sections at different elevations in order to accommodate electronic components 14 of varying heights. In the embodiment of the invention shown in the Figures, for example, the top surface 26 comprises an upper section 28 and a lower section 30 which are joined by a generally vertical section 32.

The enclosure 16 is preferably made of a heat conductive material such as metal. However, other materials, even glass or plastic, may also be used provided that the total surface area of the enclosure 16 is sufficiently large to dissipate a desired amount of the heat generated by the components 14. Furthermore, depending on the material from which it is made, the enclosure 16 may be manufactured using any of a variety of techniques, such as deep drawing, bulk machining and electroforming. The enclosure 16 may also be assembled from a number of individual components using suitable gluing or brazing techniques.

The enclosure 16 may be attached to the circuit board 12 using any known means, such as spring clamps, adhesives or, as shown in FIG. 2, screws 34. In addition, the enclosure is ideally hermetically sealed to the circuit board 12 with a suitable, preferably elastomeric, seal 36. Accordingly, the enclosure 16 and the circuit board 12 will define a sealed volume within which the electronic components 14 are located.

In accordance with the present invention, a cooling fluid is circulated within this sealed volume and evaporated on or near the components 14 in order to absorb the heat generated by the components. The vaporous cooling fluid then expands against the enclosure 16 and condenses as the heat from the fluid is transmitted through the enclosure and into the surrounding environment. The cooling fluid is preferably a dielectric fluid that will not interfere with the operation of the components 14. Several known cooling fluids are suitable for use in the present invention, including Fluorinert™, which is sold by 3M Corporation of St. Paul, Minn.

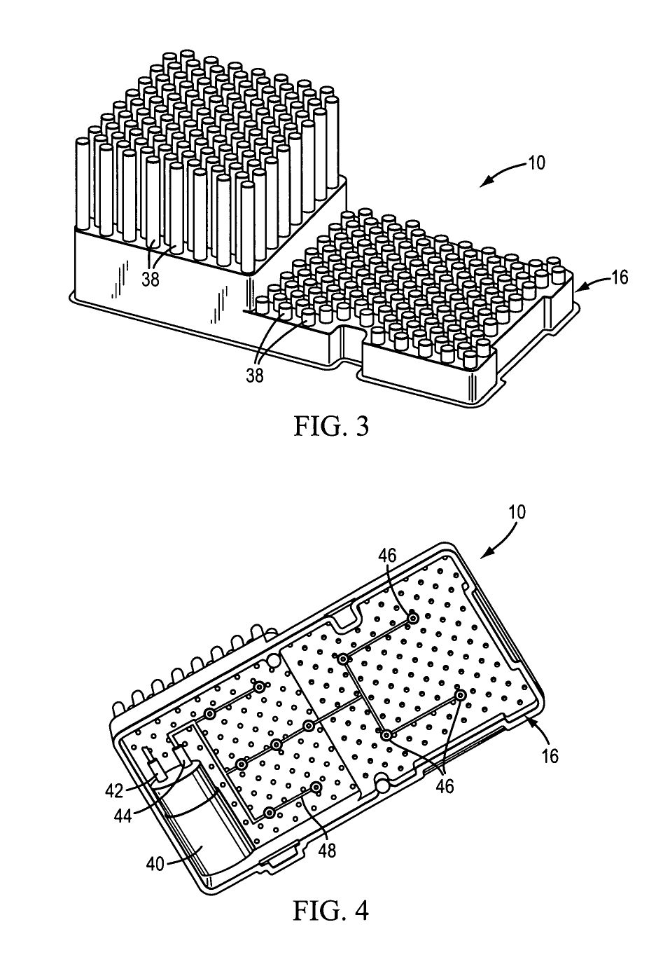

Referring also to FIGS. 3 and 4, which shows another embodiment of the present invention, the enclosure 16 may also comprise a number of condenser tubes 38 to aid in dissipating the heat from the vaporous cooling fluid. In this embodiment, the condenser tubes 38 are cylindrical members which extend generally vertically from the top surface 26 of the enclosure 16. In addition, the tops of the condenser tubes 38 are closed while their bottoms are open to the sealed volume defined by the enclosure 16 and the circuit board 12. The number and height of the condenser tubes 38 may vary depending on the volume of cooling fluid used, which in turn depends on the amount of heat which is desired to be dissipated from the individual electronic components 14. These determinations can be readily made by the person of ordinary skill in the art given a particular cooling application.

Referring to FIG. 4, the cooling fluid may be circulated to the various electronic components 14 by a pump 40. The pump may derive its power from the circuit board 12 or an external power supply, in which event the power leads for the pump are fed through a sealed feed-through in the enclosure 16. The pump 40 includes an inlet 42 which is connected to a reservoir for the cooling fluid and an outlet 44 which is connected to a number of applicators 46 by a fluid distribution network. The fluid distribution network may comprise a fluid manifold which is connected to or formed in the enclosure 16 or, in the embodiment of the invention which is shown in FIG. 4, separate lengths of a suitable tubing 48. The reservoir for the cooling fluid may comprise a bottom portion of the sealed volume or, as shown in FIG. 2, a separate catch tray 50 which is secured to the opposite side of the circuit board 12 and which communicates with the sealed volume through a number of holes or channels in the circuit board. Each applicator 46 is ideally positioned over or adjacent one or more of the electronic components 14. The applicators 46 may comprise, for example, small diameter tubes, sprayers, nozzles or atomizers.

In operation of the embodiment of the invention shown in FIGS. 3 and 4, the cooling fluid is pumped through the applicators 46 and onto or adjacent the electronic components 14. As the cooling fluid absorbs heat from the components 14 it evaporates and thereby cools the components. The vaporous cooling fluid then rises into the condenser tubes and condenses as its heat is transmitted through the condenser tubes and into the surrounding environment. The liquid cooling fluid is then drawn by gravity into the reservoir and the process is repeated to cool the components 14 for as long as desired.

It should be recognized that, while the present invention has been described in relation to the preferred embodiments thereof, those skilled in the art may develop a wide variation of structural and operational details without departing from the principles of the invention. For example, the various elements shown in the different embodiments may be combined in a manner not illustrated above. Therefore, the appended claims are to be construed to cover all equivalents falling within the true scope and spirit of the invention.

We claim:

1. An apparatus for cooling a number of electronic components which in operation generate heat, the apparatus comprising:
an enclosure within which the components are positioned;
means for circulating a cooling fluid to the components;
wherein the cooling fluid evaporates on or proximate the components and thereby absorbs the heat generated by the components;
means for condensing the evaporated cooling fluid; and
a reservoir which is in fluid communication with the circulating means and within which the condensed cooling fluid collects.

2. The apparatus of claim 1, wherein the enclosure defines a hermetically sealed volume within which the components are positioned.

3. The apparatus of claim 1, wherein the components are mounted on a circuit board and the enclosure is secured and sealed to the circuit board over the components.

4. The apparatus of claim 1, wherein the condensing means comprises a surface of the enclosure.

5. The apparatus of claim 1, wherein the condensing means comprises a number of condenser tubes which are connected to or formed integrally with the enclosure.

6. The apparatus of claim 1, wherein the condensing means comprises a plurality of condensing tubes which each extend generally vertically from an upper surface of the enclosure.

7. The apparatus of claim 1, wherein the circulating means comprises:
a pump which is fluidly connected to the reservoir;
a number of applicators which are positioned proximate the components; and
a fluid distribution network which is connected between the pump and the applicators;
wherein the cooling fluid is circulated by the pump through the fluid distribution network and the applicators to the components.

8. The apparatus of claim 7, wherein the fluid distribution network comprises a manifold which is formed within one or more surfaces of the enclosure.

9. The apparatus of claim 2, wherein the reservoir comprises a portion of the sealed volume.

10. The apparatus of claim 3, wherein the reservoir comprises a catch tray which is secured to the circuit board opposite the components.

11. The apparatus of claim 10, wherein the enclosure and the circuit board together define a hermetically sealed volume within which the components are positioned and the reservoir communicates with the sealed volume through a number of apertures in the circuit board.

12. A method for cooling a number of electronic components which in use generate heat, the method comprising:
(a) positioning the components within a sealed enclosure;
(b) circulating a cooling fluid to the components;
(c) evaporating the cooling fluid on or adjacent the components to thereby absorb the heat generated by the components;
(d) condensing the evaporated cooling fluid within the enclosure;
(e) collecting the condensed cooling fluid; and
(f) repeating steps (b) through (e).
